(19) United States
(12) Patent Application Publication
(10) Pub. No.: US 2025/0348049 A1
(43) Pub. Date: Nov. 13, 2025

(54) TESTING SYSTEM

(71) Applicant: Quanta Computer Inc., Taoyuan City (TW)

(72) Inventors: Yang-Sheng WANG, Taoyuan City (TW); Yu-Ching CHEN, Taoyuan City (TW); Chin-Hua HSU, Taoyuan City (TW); Shih-Chieh LO, Taoyuan City (TW)

(21) Appl. No.: 18/767,271

(22) Filed: Jul. 9, 2024

(30) Foreign Application Priority Data
May 8, 2024 (TW) 113116976

(51) Int. Cl. G05B 19/042; G05B 9/02; G05B 23/02

(52) U.S. Cl. CPC G05B 19/0428; G05B 9/02; G05B 23/0256

(57) ABSTRACT

A testing system includes a motor device, a driving device, a peripheral device and a testing device. The testing device generates testing parameters for testing the motor device, the driving device, and the peripheral device and determines the testing state of each of the motor device, the driving device and the peripheral device.

### CROSS REFERENCE TO RELATED APPLICATIONS

This application claims priority of Taiwan Patent Application No. 113116976, filed on May 8, 2024, the entirety of which is incorporated by reference herein.

### BACKGROUND OF THE INVENTION

### Field of the Invention

The present invention relates to a testing system, and in particular it relates to a testing system for increasing the safety of testing.

### Description of the Related Art

Technology developed to such a degree that inverters can be used in future motor control along with high-voltage electrical systems. In addition, since there are inherent risks associated with the use of a high-voltage electrical system to perform verification of semi-finished products, it is therefore important to safely monitor said verification. In general, when verifying an inverter, a large number of complex parameters need to be input, including setting the different motor parameters, the different control parameters of the inverter, and the different control parameter of the peripheral equipment according to different motors.

However, these settings are often manually input by testers, and key parameters may be input incorrectly, raising safety concerns for personnel and potentially damaging the equipment. When an error occurs, it also increases the difficulty of debugging. Therefore, how to effectively increase the safety of testing has become a focus for technical improvements by various manufacturers.

### BRIEF SUMMARY OF THE INVENTION

An embodiment of the present invention provides a testing system, thereby effectively increasing the safety of testing, and decreasing the risk of incorrect input of test parameters and incorrect selection of devices under test.

An embodiment of the present invention provides a testing system, which includes a motor device, a driving device, a peripheral device and a testing device. The testing device is connected to the motor device, the driving device, and the peripheral device. The testing device is configured to generate a plurality of testing parameters for testing the motor device, the driving device, and the peripheral device. The testing device is configured to determine the testing state of each of the motor device, the driving device and the peripheral device.

According to the testing system disclosed by the present invention, the testing device determines whether the specification of the motor device matches the specification of the driving device, determine whether the specification of the driving device matches the specification of the peripheral device, determine whether the initial operating parameter of each of the driving device and the peripheral device is within the operating range and determine whether the testing control parameter of each of the driving device and the peripheral device is within the safety range. When determining that the specification of the motor device matches the specification of the driving device, the specification of the driving device matches the specification of the peripheral device, the initial operating parameters are within the operating range and the testing control parameters are within the safety range, the testing device generates the testing parameters for testing the motor device, the driving device, and the peripheral device according to the initial operating parameters and the testing control parameters. In the testing period, the testing device monitors and obtains the monitoring parameter of each of the motor device, the driving device, and the peripheral device, and determines the testing state of each of the motor device, the driving device and the peripheral device according to the monitoring parameters. Therefore, it may effectively increase the safety of testing, and decrease the risk of incorrect input of test parameters and incorrect selection of devices under test (such as the motor device, the driving device, and the peripheral device.

### BRIEF DESCRIPTION OF THE DRAWINGS

The present invention can be more fully understood by reading the subsequent detailed description and examples with references made to the accompanying drawings, wherein:

FIG. 1 is a schematic view of a testing system according to an embodiment of the present invention;

FIG. 2 is a schematic view of a testing device according to an embodiment of the present invention;

FIGS. 3A and 3B are a flowchart of an operation method of a testing system according to an embodiment of the present invention; and

FIGS. 4A, 4B and 4C are a flowchart of an operation method of a testing system according to another embodiment of the present invention.

### DETAILED DESCRIPTION OF THE INVENTION

In each of the following embodiments, the same reference number represents an element or component that is the same or similar.

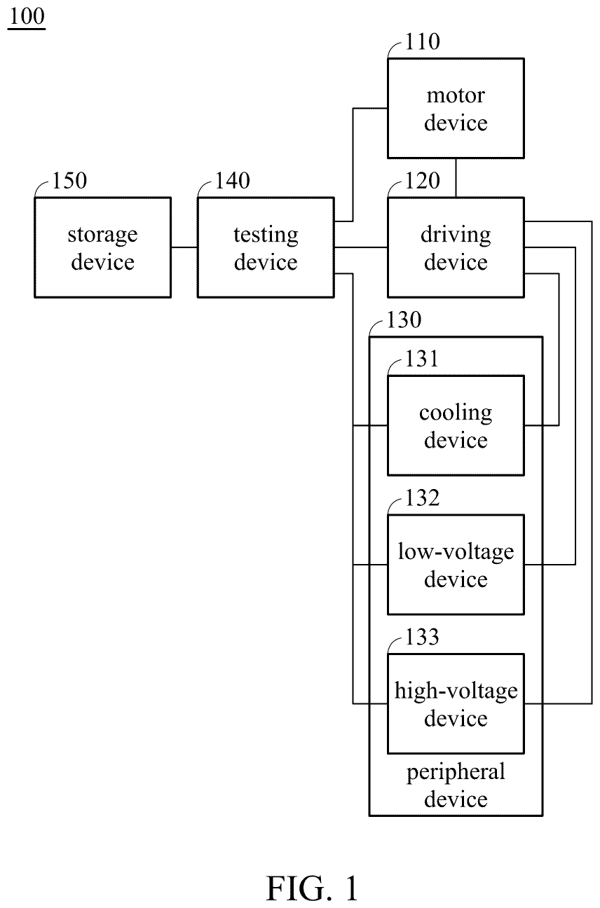

FIG. 1 is a schematic view of a testing system according to an embodiment of the present invention. Please refer to FIG. 1. The testing system 100 may include a motor device 110, a driving device 120, a peripheral device 130 and a testing device 140.

In some embodiments, the motor device 110 may include a physical motor or a virtual motor, but the embodiment of the present invention is not limited thereto. The driving device 120 may be connected to the motor device 110. The driving device 120 may generate the driving signal to drive the motor device 110 to operate according to the control signal or the testing signal. In some embodiments, the driving device 120 may be an inverter, but the embodiment of the present invention is not limited thereto.

The peripheral device 130 may be connected to the driving device 120. In some embodiments, the peripheral device 130 may include a cooling device 131, a low-voltage device 132 and a high-voltage device 133, but the embodiment of the present invention is not limited thereto. The cooling device 131 may be connected to the driving device 120, and cool the operating temperature of the driving device 120. In addition, the cooling device 131 may be a chiller. The low-voltage device 132 may be connected to the driving device 120, and provide the low-voltage to the driving device 120. The high-voltage device 133 may be connected to the driving device 120, and provide the high-voltage to the driving device 120.

The testing device 140 may be connected to the motor device 110, the driving device 120 and the peripheral device 130. The testing device 140 may determine whether the specification of the motor device 110 matches the specification of the driving device 120. Furthermore, the testing device 140 may determine whether a voltage plateau, a continuous power and an operating voltage range in the specification of the driving 120 are covered by the specification of the motor device 110.

For example, when the voltage plateau of the driving device 120 is 800 V, the continuous power of the driving device 120 is 110 KW, the operating voltage range of the driving device 120 is 380˜865 V, the voltage plateau of the motor device 110 is 800 V, the continuous power of the motor device 110 is 300 kW and the operating voltage range of the motor device is 0˜1000 V, the testing device 140 may determine that the specification of the driving device 120 may be covered by the specification of the motor device 110, so as to determine that the specification of the motor device 110 matches the specification of the driving device 120. When the voltage plateau of the driving device 120 is 800 V, the continuous power of the driving device 120 is 110 KW, the operating voltage range of the driving device 120 is 380˜865 V, the voltage plateau of the motor device 110 is 400 V, the continuous power of the motor device 110 is 100 KW and the operating voltage range of the motor device is 0˜500 V, the testing device 140 may determine that the specification of the driving 120 does not covered by the specification of the motor device 110, so as to determine that the specification of the motor device 110 does not match the specification of the driving device 120.

The testing device 140 may determine whether the specification of the driving device 120 matches the specification of the peripheral device 130. Furthermore, the testing device 140 may determine whether a high-voltage operating range, a low-voltage operating range and an operating temperature range in the specification of the driving device 120 are covered by the specification of the peripheral device 130, so as to determine whether the specification of the driving device 120 matches the specification of the peripheral device 130.

For example, when the high-voltage operating range of the driving device 120 is 380˜865 V, the low-voltage operating range of the driving device 120 is 9˜16 V, the operating temperature range of the driving device 120 is −20˜85° C., the high-voltage operating range of the peripheral device 130 is 0˜1000 V, the low-voltage operating range of the peripheral device 130 is 0˜30 V and the operating temperature range of the peripheral device 130 is −40˜90° C., the testing device 140 may determine that the specification of the driving device 120 is covered by the specification of the peripheral device 130, so as to determine that the specification of the driving device 120 matches the specification of the peripheral device 130. When the high-voltage operating range of the driving device 120 is 380˜865 V, the low-voltage operating range of the driving device 120 is 9˜16 V, the operating temperature range of the driving device 120 is −20˜85° C., the high-voltage operating range of the peripheral device 130 is 0˜500 V, the low-voltage operating range of the peripheral device 130 is 15˜30 V and the operating temperature range of the peripheral device 130 is −10˜80° C., the testing device 140 may determine that the specification of the driving device 120 does not covered by the specification of the peripheral device 130, so as to determine that the specification of the driving device 120 does not match the specification of the peripheral device 130.

The testing device 140 may determine whether an initial operating parameter of each of the driving device 120 and the peripheral device 130 is within the operating range. Furthermore, the testing device 140 may determine whether the initial operating parameter of each of the driving device 120 and the peripheral device 130 set by the user is within the operating range.

For example, when the voltage plateau of the operating range is 800 V, the continuous power of the operating range is 110 KW, the high-voltage operating range of the operating range is 380˜865 V, the low-voltage operating range of the operating range is 9˜16 V, the operating temperature range of the operating range is −20˜85° C., the voltage plateau in the initial operating parameter of each of the driving device 120 and the peripheral device 130 is 800 V, the continuous power in the initial operating parameter of each of the driving device 120 and the peripheral device 130 is 110 KW, the high-voltage in the initial operating parameter of each of the driving device 120 and the peripheral device 130 is 500 V, the low-voltage in the initial operating parameter of each of the driving device 120 and the peripheral device 130 is 13.8 V and the operating temperature in the initial operating parameter of each of the driving device 120 and the peripheral device 130 is 65° C., the testing device 140 may determine that the initial operating parameter of each of the driving device 120 and the peripheral device 130 is within the operating range.

The testing device 140 may determine whether a testing control parameter of each of the driving device 120 and the peripheral device 130 is within the safety range. Furthermore, the testing device 140 may determine whether the testing control parameter of each of the driving device 120 and the peripheral device 130 set by the user is within the safety range.

For example, when the testing control parameter of each of the driving device 120 and the peripheral device 130 rises from 580 V to 800 V and the safety range is 380˜865 V, since 800 V does not exceed 865 V, the testing device 140 may determine that the testing control parameter of each of the driving device 120 and the peripheral device 130 is within the safety range. When the testing control parameter of each of the driving device 120 and the peripheral device 130 rises from 580 V to 870 V and the safety range is 380˜865 V, since 870 V exceeds 865 V, the testing device 140 may determine that the testing control parameter of each of the driving device 120 and the peripheral device 130 is not within the safety range.

In addition, when the testing device 140 determines that the specification of the motor device 110 matches the specification of the driving device 120, the specification of the driving device 120 matches the specification of the peripheral device 130, the initial operating parameters are within the operating range and the testing control parameters are within the safety range, the testing device 140 may generate the testing parameters for testing the motor device 110, the driving device 120 and the peripheral device 130 according to the initial operating parameters and the testing control parameters. Therefore, it may effectively increase the safety of testing, and decrease the risk of incorrect input of test parameters and incorrect selection of devices under test (such as the motor device 110, the driving device 120 and the peripheral device 130).

Furthermore, when determining that the specification of the motor device 110 does not match the specification of the driving device 120, the specification of the driving device 120 does not match the specification of the peripheral device 130, the initial operating parameters are not within the operating range, or the testing control parameters are not within the safety range, the testing device 140 may further generate an error message.

Then, in the testing period, the testing device 140 may monitor and obtain the monitoring parameter of each of the motor device 110, the driving device 120, and the peripheral device 130, and determine the testing state of each of the motor device 110, the driving device 120 and the peripheral device 130 according to the monitoring parameters. Furthermore, the testing device 140 may compare the monitoring parameter of each of the motor device 110, the driving device 120 and the peripheral device 130 with a predetermined value, so as to determine whether the monitoring parameter matches the predetermined value. When determining that the monitoring parameter matches the predetermined value, the testing device 140 may determine that the testing state of each of the motor device 110, the driving device 120 and the peripheral device 130 is the normal state. When determining that the monitoring parameter does not match the predetermined value, the testing device 140 may determine that the testing state of each of the motor device 110, the driving device 120 and the peripheral device 130 is the abnormal state.

In some embodiments, when the testing device 140 determines that the testing state of each of the motor device 110, the driving device 120 and the peripheral device 130 is the normal state, the testing device 140 may generate a testing completion message, which indicates that the testing result is the same as the expected result. In addition, when the testing device 140 determines that the testing state of each of the motor device 110, the driving device 120 and the peripheral device 130 is the abnormal state, the testing device 140 may generate the testing abnormal message, which indicates that at least one of the motor device 110, the driving device 120 and the peripheral device 130 is abnormal. At the same time, the testing device 140 may activate a protection mechanism to cause the testing system 100 to stop testing, so as to avoid damage to the motor device 110, the driving device 120 and the peripheral device 130 in the testing process.

Furthermore, in some embodiments, the testing device 140 may further obtain device identifier of each of the motor device 110, the driving device 120 and the peripheral device 130, and the testing device 140 may further obtain the specification of the motor device 110, the specification of the driving device 120 and the specification of the peripheral device 130 according to the device identifier of each of the motor device 110, the driving device 120 and the peripheral device 130.

In some embodiments, the testing system 100 further includes a storage device 150. The storage device 150 may be connected to the testing device 140. The storage device 150 may store the specification of the motor device 110, the specification of the driving device 120, the specification of the peripheral device 130, the initial operating parameters and the testing control parameters. For example, the user may obtain the specification of the motor device 110, the specification of the driving device 120 and the specification of the peripheral device 130 and set the initial operating parameters and the testing control parameters in advance, and then store the specification of the motor device 110, the specification of the driving device 120, the specification of the peripheral device 130, the initial operating parameters and the testing control parameters in the storage device 150. In some embodiments, the storage device 150 may be a memory, a hard disk, a solid state disk, etc., but the embodiment of the present invention is not limited thereto.

In an entire operation of the testing system 100, first, the testing device 140 may obtain the device identifier of each of the motor device 110, the driving device 120 and the peripheral device 130. Then, the testing device 140 may obtain the specification of the motor device 110, the specification of the driving device 120 and the specification of the peripheral device 130 from the storage device 150 according to the device identifier of each of the motor device 110, the driving device 120 and the peripheral device 130.

Afterward, the testing device 140 may determine whether the specification of the motor device 110 matches the specification of the driving device 120. When determining that the specification of the motor device 110 does not match the specification of the driving device 120, the testing device 140 may generate the error message, which indicates that the specification of the motor device 110 does not match the specification of the driving device 120.

When determining that the specification of the motor device 110 matches the specification of the driving device 120, the testing device 140 may determine whether the specification of the driving device 120 matches the specification of the peripheral device 130. When determining that the specification of the driving device 120 does not match the specification of the peripheral device 130, the testing device 140 may generate the error message, which indicates that the specification of the driving device 120 does not match the specification of the peripheral device 130.

When determining that the specification of the driving device 120 matches the specification of the peripheral device 130, the testing device 140 may determine whether the initial operating parameter of each of the driving device 120 and the peripheral device 130 is within the operating range. When determining that the initial operating parameter of each of the driving device 120 and the peripheral device 130 is not within the operating range, the testing device 140 may generate the error message, which indicates that the initial operating parameter of each of the driving device 120 and the peripheral device 130 is not within the operating range.

When determining that the initial operating parameter of each of the driving device 120 and the peripheral device 130 is within the operating range, the testing device 140 may determine whether the testing control parameter of each of the driving device 120 and the peripheral device 130 is within the safety range. When determining that the testing control parameter of each of the driving device 120 and the peripheral device 130 is not within the safety range, the testing device 140 may generate the error message, which indicates that the testing control parameter of each of the driving device 120 and the peripheral device 130 is not within the safety range.

When determining that the testing control parameter of each of the driving device 120 and the peripheral device 130 is within the safety range, the testing device 140 may generate the testing parameters for testing the motor device 110, the driving device 120 and the peripheral device 130 according to the initial operating parameters and the testing control parameters.

Then, in the testing period, the testing device 140 may monitor and obtain the monitoring parameter of each of the motor device 110, the driving device 120 and the peripheral device 130, and determine the testing state of each of the motor device 110, the driving device 120 and the peripheral device 130 according to the monitoring parameters.

Afterward, when the testing device 140 determines that the testing state of each of the motor device 110, the driving device 120 and the peripheral device 130 is the normal state, the testing device 140 may generate the testing completion message, which indicates that the testing result is the same as the expected result. In addition, when the testing device 140 determines that the testing state of each of the motor device 110, the driving device 120 and the peripheral device 130 is the abnormal state, the testing device 140 may generate the testing abnormal message, which indicates that at least one of the motor device 110, the driving device 120 and the peripheral device 130 is abnormal. At the same time, the testing device 140 may activate the protection mechanism to cause the testing system 100 to stop testing, so as to avoid damage to the motor device 110, the driving device 120 and the peripheral device 130 in the testing process.

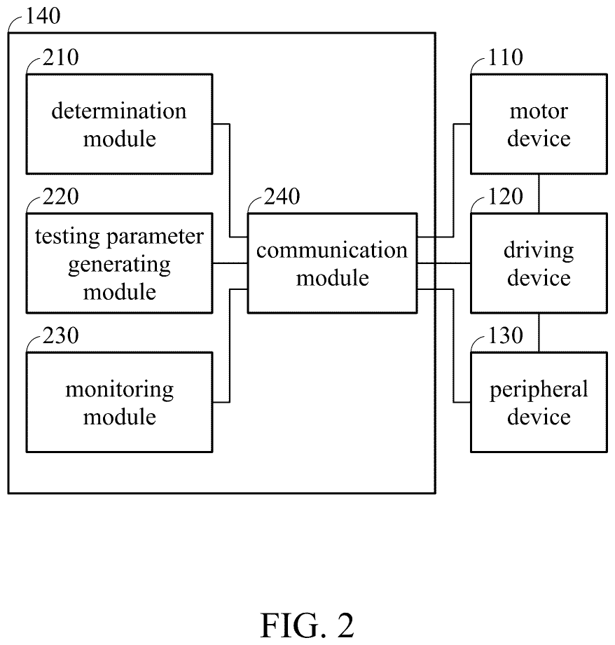

FIG. 2 is a schematic view of a testing device according to an embodiment of the present invention. Please refer to FIG. 2. The testing device 140 may include a determination module 210, a testing parameter generating module 220 and a monitoring module 230.

The determination module 210 is configured to determine whether the specification of the motor device 110 matches the specification of the driving device 120, determine whether the specification of the driving device 120 matches the specification of the peripheral device 130, determine whether the initial operating parameter of each of the driving device 120 and the peripheral device 130 is within the operating range, determine whether the testing control parameter of each of the driving device 120 and the peripheral device 130 is within the safety range.

When determining that the specification of the motor device 110 matches the specification of the driving device 120, the specification of the driving device 120 matches the specification of the peripheral device 130, the initial operating parameters are within the operating range and the testing control parameters are within the safety range, the determination module 210 may generate a determination completion signal. In addition, when determining that the specification of the motor device 110 does not match the specification of the driving device 120, the specification of the driving device 120 does not match the specification of the peripheral device 130 the initial operating parameters are not within the operating range, or the testing control parameters are not within the safety range, the determination module 210 may generate an error message.

The testing parameter generating module 220 may be connected to the determination module 210. The testing parameter generating module 210 may generate the testing parameters for testing the motor device 110, the driving device 120 and the peripheral device 130 according to the determination completion signal, the initial operating parameters and the testing control parameters

In the testing period, the monitoring module 230 may monitor and obtain a monitoring parameter of each of the motor device 110, the driving device 120 and the peripheral device 130, and determine the testing state of each of the motor device 110, the driving device 120 and the peripheral device 130 according to the above monitoring parameters. Furthermore, when the monitoring module 230 may further determine that the testing state of each of the motor device 110, the driving device 120 and the peripheral device 130 is a normal state, the monitoring module 230 may generate the testing completion message. In addition, when the monitoring module 230 determines that the testing state of each of the motor 110, the driving device 120 and the peripheral device 130 is an abnormal state, the monitoring module 230 may generate the testing abnormal message and activate a protection mechanism.

In addition, in some embodiments, the testing device 140 further includes a communication module 240. The communication module 240 may connected to the motor device 110, the driving device 120, the peripheral device 130, the determination module 210, the testing parameter generating module 220 and the monitoring module 230, so that the motor device 110, the driving device 120, the peripheral device 130, the determination module 210, the testing parameter generating module 220 and the monitoring module 230 perform the signal and data transmission through the communication module 240.

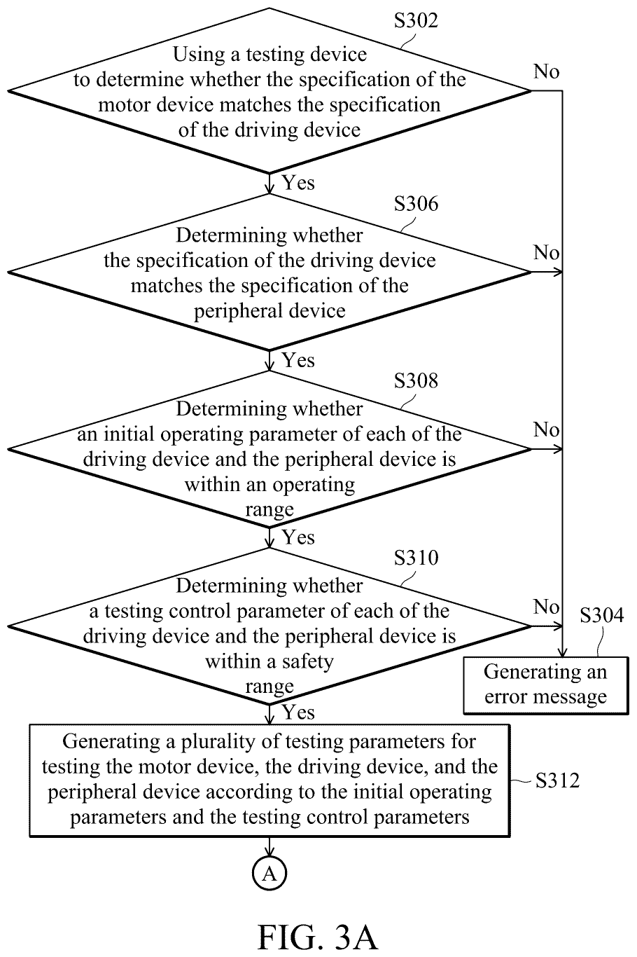

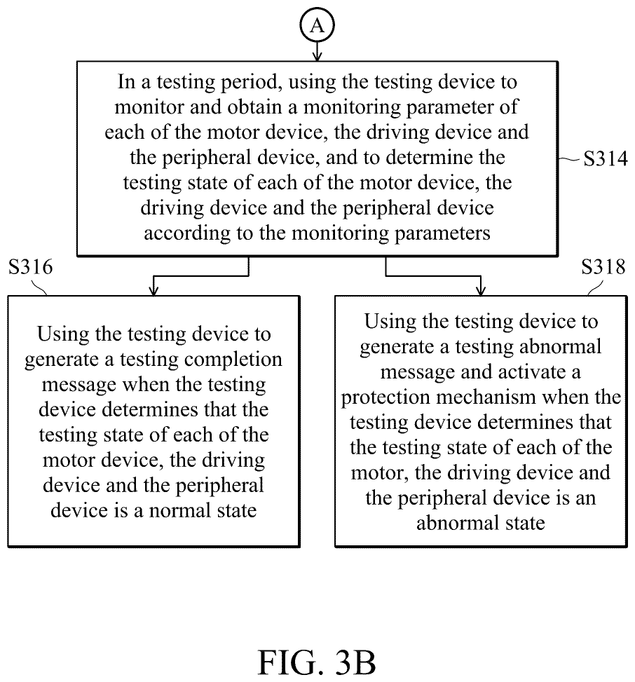

FIGS. 3A and 3B are a flowchart of an operation method of a testing system according to an embodiment of the present invention. In step S302, the method involves using a testing device to determine whether the specification of the motor device matches the specification of the driving device. When determining that the specification of the motor device does not match the specification of the driving device, the method performs step S304. In step S304, the method involves generating an error message.

When determining that the specification of the motor device matches the specification of the driving device, the method performs step S306. In step S306, the method involves determining whether the specification of the driving device matches the specification of the peripheral device. When determining that the specification of the driving device does not match the specification of the peripheral device, the method performs step S304. In step S304, the method involves generating an error message.

When determining that the specification of the driving device matches the specification of the peripheral device, the method performs step S308. In step S308, the method involves determining whether an initial operating parameter of each of the driving device and the peripheral device is within an operating range. When determining that initial operating parameter of each of the driving device and the peripheral device is not within the operating range, the method performs S304. In step S304, the method involves generating an error message.

When determining that the initial operating parameter of each of the driving device and the peripheral device is within the operating range, the method performs step S310. In step S310, the method involves determining whether a testing control parameter of each of the driving device and the peripheral device is within a safety range. When determining that the testing control parameter of each of the driving device and the peripheral device is not within the safety range, the method performs step S304. In step S304, the method involves generating an error message.

When determining that the testing control parameter of each of the driving device and the peripheral device is within the safety range, the method performs step S312. In step S312, the method involves generating a plurality of testing parameters for testing the motor device, the driving device, and the peripheral device according to the initial operating parameters and the testing control parameters.

In step S314, the method involves in a testing period, using the testing device to monitor and obtain a monitoring parameter of each of the motor device, the driving device and the peripheral device, and to determine the testing state of each of the motor device, the driving device and the peripheral device according to the monitoring parameters.

In step S316, the method involves using the testing device to generate a testing completion message when the testing device determines that the testing state of each of the motor device, the driving device and the peripheral device is a normal state. In step S318, the method involves using the testing device to generate a testing abnormal message and activate a protection mechanism when the testing device determines that the testing state of each of the motor, the driving device and the peripheral device is an abnormal state.

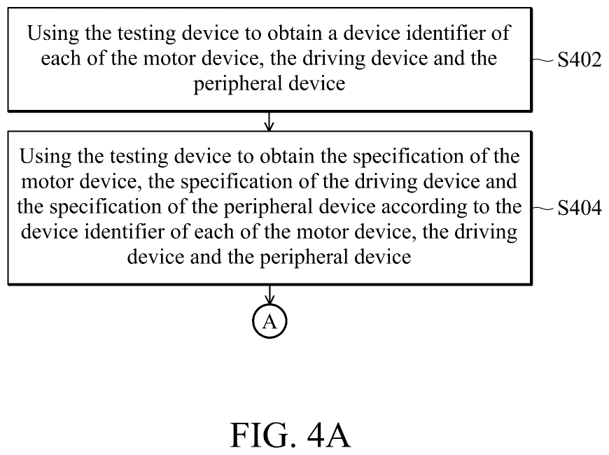

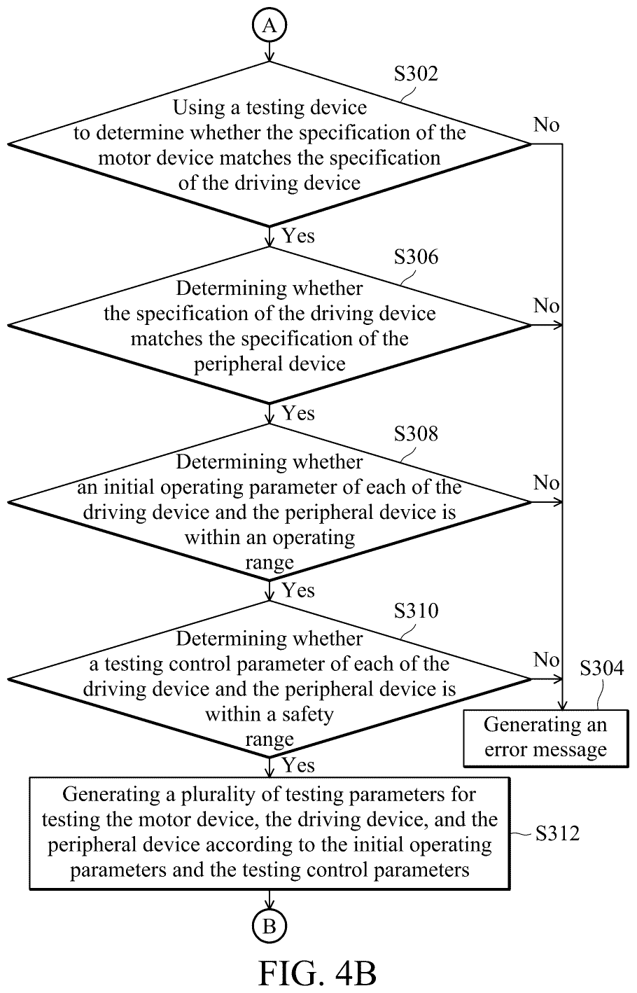

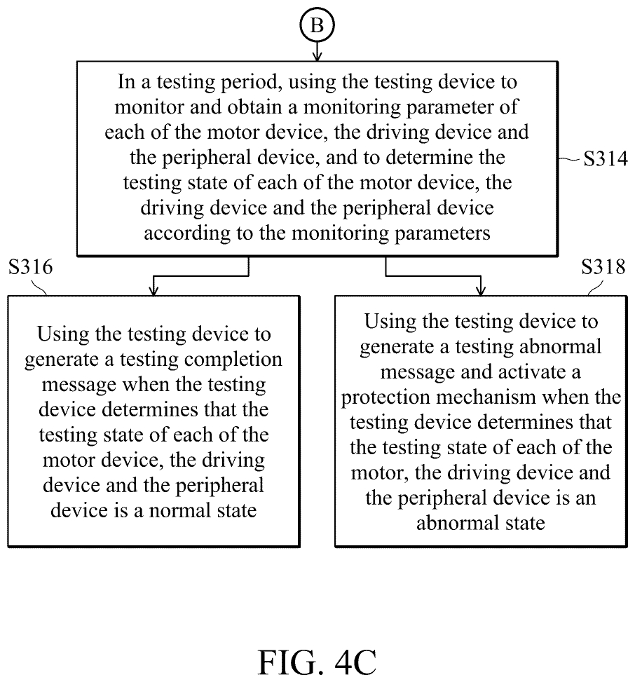

FIGS. 4A, 4B and 4C are a flowchart of an operation method of a testing system according to another embodiment of the present invention. In the embodiment, steps S302˜S318 in FIGS. 4B and 4C are the same as or similar to steps S302˜S318 in FIGS. 3A and 3B. Accordingly, steps S302˜318 in FIGS. 4B and 4C may refer to the description of the embodiment of FIGS. 3A and 3B, and the description thereof is not repeated herein.

In step S402, the method involves using the testing device to obtain a device identifier of each of the motor device, the driving device and the peripheral device. In step S404, the method involves using the testing device to obtain the specification of the motor device, the specification of the driving device and the specification of the peripheral device according to the device identifier of each of the motor device, the driving device and the peripheral device.

It should be noted that the order of the steps of FIG. 3A, FIG. 3B, FIG. 4A, FIG. 4B and FIG. 4C is only for illustrative purposes, and is not intended to limit the order of the steps of the present invention. The user may change the order of the steps above to meet specific requirements. The flowcharts described above may add additional steps or use fewer steps without departing from the spirit and scope of the present invention.

In summary, according to the testing system disclosed by the embodiment of the present invention, the testing device determines whether the specification of the motor device matches the specification of the driving device, determine whether the specification of the driving device matches the specification of the peripheral device, determine whether the initial operating parameter of each of the driving device and the peripheral device is within the operating range and determine whether the testing control parameter of each of the driving device and the peripheral device is within the safety range. When determining that the specification of the motor device matches the specification of the driving device, the specification of the driving device matches the specification of the peripheral device, the initial operating parameters are within the operating range and the testing control parameters are within the safety range, the testing device generates the testing parameters for testing the motor device, the driving device, and the peripheral device according to the initial operating parameters and the testing control parameters. In the testing period, the testing device monitors and obtains the monitoring parameter of each of the motor device, the driving device and the peripheral device, and determines the testing state of each of the motor device, the driving device and the peripheral device according to the monitoring parameters. Therefore, it may effectively increase the safety of testing, and decrease the risk of incorrect input of test parameters and incorrect selection of devices under test (such as the motor device, the driving device, and the peripheral device.

While the present invention has been described by way of example and in terms of the preferred embodiments, it should be understood that the present invention is not limited to the disclosed embodiments. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A testing system, comprising:
a motor device;
a driving device;
a peripheral device; and
a testing device, connected to the motor device, the driving device, and the peripheral device, wherein the testing device is configured to generate a plurality of testing parameters for testing the motor device, the driving device, and the peripheral device, and the testing device is configured to determine a testing state of each of the motor device, the driving device and the peripheral device.

2. The testing system as claimed in claim 1, further comprising:
a storage unit, connected to the testing device, and configured to store a specification of the motor device, a specification of the driving device, a specification of the peripheral device, a plurality of initial operating parameters and a plurality of testing control parameters.

3. The testing system as claimed in claim 1, wherein the testing device comprises:
a determination module, configured to determine whether a specification of the motor device matches a specification of the driving device, determine whether the specification of the driving device matches a specification of the peripheral device, determine whether an initial operating parameter of each of the driving device and the peripheral device is within an operating range, and determine whether a testing control parameter of each of the driving device and the peripheral device is within a safety range, wherein when determining that the specification of the motor device matches the specification of the driving device, the specification of the driving device matches the specification of the peripheral device, the initial operating parameters are within the operating range and the testing control parameters are within the safety range, the determination module is configured to generate a determination completion signal;
a testing parameter generating module, connected to the determination module, wherein the testing parameter generating module is configured to generate the plurality of testing parameters for testing the motor device, the driving device, and the peripheral device according to the determination completion signal, the initial operating parameters and the testing control parameters; and
a monitoring module, wherein in a testing period, the monitoring module is configured to monitor and obtain a monitoring parameter of each of the motor device, the driving device and the peripheral device, and determine the testing state of each of the motor device, the driving device and the peripheral device according to the monitoring parameters.

4. The testing system as claimed in claim 3, wherein when determining that the specification of the motor device does not match the specification of the driving device, the specification of the driving device does not match the specification of the peripheral device, the initial operating parameters are not within the operating range, or the testing control parameters are not within the safety range, the determination module is configured to generate an error message.

5. The testing system as claimed in claim 3, wherein the testing device further comprises a communication module connected to the motor device, the driving device, the peripheral device, the determination module, the testing parameter generating module and the monitoring module.

6. The testing system as claimed in claim 1, wherein the testing device is further configured to obtain a device identifier of each of the motor device, the driving device and the peripheral device, and the testing device is further configured to obtain a specification of the motor device, a specification of the driving device, and a specification of the peripheral device according to the device identifier of each of the motor device, the driving device and the peripheral device.

7. The testing system as claimed in claim 1, wherein when determining that a specification of the motor device does not match a specification of the driving device, the specification of the driving device does not match a specification of the peripheral device, initial operating parameters are not within the operating range, or testing control parameters are not within the safety range, the testing device is further configured to generate an error message.

8. The testing system as claimed in claim 1, wherein when the testing device determines that the testing state of each of the motor device, the driving device and the peripheral device is a normal state, the testing device is configured to generate a testing completion message, and when the testing device determines that the testing state of each of the motor, the driving device and the peripheral device is an abnormal state, the testing device is configured to generate a testing abnormal message and activate a protection mechanism.

9. The testing system as claimed in claim 1, wherein the driving device is an inverter.

10. The testing system as claimed in claim 1, wherein the peripheral device comprises a cooling device, a low-voltage device and a high-voltage device.
